(19) United States
(12) Patent Application Publication
(10) Pub. No.: US 2009/0136663 A1
(43) Pub. Date: May 28, 2009

(54) VACUUM VAPOR DEPOSITION APPARATUS AND METHOD, AND VAPOR DEPOSITED ARTICLE FORMED THEREWITH

(75) Inventors: Shinji SANO, Matsumoto City (JP); Hiromichi GOHARA, Matsumoto City (JP); Toshio HAMA, Matsumoto City (JP); Hiroshi KIMURA, Matsumoto City (JP)

Correspondence Address: ROSSI, KIMMS & McDOWELL LLP., 20609 Gordon Park Square, Suite 150, Ashburn, VA, 20147, US

(73) Assignee: FUJI ELECTRIC HOLDINGS CO., LTD., Kawasaki-ku (JP)

(21) Appl. No.: 12/274,342

(22) Filed: Nov. 19, 2008

(30) Foreign Application Priority Data
Nov. 21, 2007 (JP) 2007-302265

(51) Int. Cl. C23C 16/04

(52) U.S. Cl. 427/248.1; 118/720

(57) ABSTRACT

When the ratio of a guest material to a host material is extremely small, it is difficult to maintain, with good accuracy, the ratio of the guest material to be vapor-deposited on the work surface and the distribution state of the guest material. The vacuum vapor deposition apparatus and method includes providing a shielding member, positioned between a first vapor deposition source and a substrate to be coated so that the vapor deposition amount of the guest material on the substrate surface is significantly less than the vapor deposition amount of the host material. A shielding member drive mechanism rotates the shielding member about a first axis while rotating the shielding member about a second axis, which is spaced from and parallel to the first axis.

### BACKGROUND

In a vacuum vapor deposition apparatus, a vapor deposition source accommodating a vapor deposition material and a work are disposed facing each other within a vacuum chamber, the vapor deposition source is heated after the vacuum chamber has been evacuated, the vapor deposition material is melted, and the vapor deposition material gasified by evaporation or sublimation is deposited on the work surface. A vapor deposition layer formed on the work surface is suitable for producing, e.g., functional layers of organic electroluminescence elements or the like. In particular, when a host material, which is a first main vapor deposition material, is doped with a guest material, which is a second vapor deposition material, used in a micro amount, a co-deposition method is generally employed in which the host material and guest materials are simultaneously vapor deposited within the same vacuum chamber. A specific co-deposition method is described in Japanese Patent Application Laid-open No. 2003-193217 (hereafter the Reference).

The Reference describes that when the ratio of the guest material to the host material in the vapor deposited layer is set to about 1/100, the vapor deposited layer with the target ratio can be obtained by setting the vapor deposition rate of the guest material on the work surface to 1/100 the vapor deposition rate of the host material. When the ratio of the guest material to the host material in the vapor deposited layer formed on the work is small, for example about 1/100, by disposing a film thickness monitor for the guest material closer to the vapor deposition source thereof than the film thickness monitor of the host material, it is possible to increase the apparent vapor deposition rate of the guest material and facilitate the monitoring of the vapor deposition rate of the guest material. Where the ratio of the guest material to the host material is very small, however, for example 1/1000 or less, even if the film thickness monitor for the guest material is disposed close to the vapor deposition source thereof, because the co-deposition treatment is realized in the vicinity of the detection limit of the monitor (0.001 Å per second), the ratio of the guest material or the distribution of the guest material to the host material is difficult to maintain with good accuracy.

In the configuration described in the Reference, a substrate (work) for vapor deposition is also rotated in addition to a shielding plate with an opening in the form of a hole or a mesh, to thereby improve the distribution evenness of the guest material formed as a film on the substrate surface. The two drive sources, however, have to be accommodated within the vacuum chamber of the vacuum vapor deposition apparatus, making the mechanism within the vacuum chamber complex. In particular, it is highly undesirable for the work, on which a vapor deposition layer is to be formed, to be driven because the impurities generated from the driving mechanism in this process can adhere to the work surface.

A method different from the technology disclosed in the Reference has also been considered. With this method, the vapor deposition rate of the host material is intentionally increased by raising the heating temperature of the vapor deposition source containing the host material and the vapor deposition rate of the guest material is maintained at a minimum controllable level by lowering the heating temperature of the vapor deposition source containing the guest material to a minimum allowable limit. But in that method, the heating temperature of the host material has to be increased to above the necessary level, thereby creating a risk of structurally modifying, such as decomposition, of the host materials.

Accordingly, there still remains a need for a vacuum vapor deposition apparatus or method that makes it possible, when two different vapor deposition materials are simultaneously vapor deposited on to a work, such as a substrate, to form a film of a guest material on the work surface with high accuracy and with more uniform distribution, even when the ratio of one vapor deposition material serving as the guest material to the other vapor deposition material serving as a host material is extremely small, for example, 1/1000 or less. The present invention addresses this need.

### SUMMARY OF THE INVENTION

The present invention relates to a vacuum vapor deposition apparatus and method for vapor depositing first and second vapor deposition materials on a work surface, a vacuum vapor deposition method, and a vapor deposited article obtained therewith.

One aspect of the present invention is a vacuum vapor deposition apparatus including a vacuum chamber, first and second vapor deposition sources disposable within the vacuum chamber, a work holding device configured to fixedly hold a work inside the vacuum chamber, the work having a surface onto which first and second vapor deposition materials supplied from the first and second vapor deposition sources are depositable. The apparatus further includes a shielding member positioned between the first vapor deposition source and the work held by the work holding device and configured to allow a vapor deposition amount of the first vapor deposition material deposited on the work surface to be less than a vapor deposition amount of the second vapor deposition material deposited on the work surface. A shielding member drive mechanism rotates the shielding member about a first axis while moving the shielding member with respect to a second axis that is spaced from the first axis. At least one drive source drives the shielding member via the shielding member drive mechanism.

The shielding member has a plurality of openings for passing the first vapor deposition material therethrough. The sum total of a surface area of the openings with respect to a surface area of the shielding member can be within a range of from 1% to 50%. The shielding member can be a disk, with the first axis extending perpendicular to a major surface of the shielding member and through the center thereof, and with the second axis parallel to the first axis. The movement of the shielding member with respect to the second axis is a rotation of the shielding member about the second axis while the shield member is rotating about the first axis.

The ratio of the vapor deposition amount of the first vapor deposition material deposited on the work surface to the vapor deposition amount of the second vapor deposition material deposited on the work surface can be 1/1000 or less.

Another aspect of the present invention is a vacuum vapor deposition method of depositing the first and second vapor deposition materials, supplied from the first and second vapor deposition sources disposed within the vacuum chamber, on the surface of the work fixedly held inside the vacuum chamber. The method includes disposing the shielding member, which shields part of the first vapor deposition material supplied from the first vapor deposition source, between the first vapor deposition source and the work, and moving the shielding member about at least two spaced axes while depositing the first and second deposition materials on the work surface.

The moving step includes moving the shielding member about a plane that includes a major surface of the shielding member. The moving step includes rotating the shielding member about a first axis while revolving the shielding member about a second axis that is spaced from and parallel with the first axis. The rotation speed of the shielding member about the first axis can be within a range of from 1 rpm to 100 rpm. The rotation speed of the shielding member about the second axis can be within a range of from 1 rpm to 100 rpm.

The vapor deposition rate of the first vapor deposition material on the work surface can be within a range of from 0.0001 Å per second to 0.1 Å per second. The ratio of the vapor deposition amount of the first vapor deposition material deposited on the work surface to the vapor deposition amount of the second vapor deposition material deposited on the work surface can be 1/1000 or less.

### BRIEF DESCRIPTION OF THE DRAWINGS

FIG. 1 is a diagram schematically illustrating the first embodiment of the vacuum vapor deposition apparatus in accordance with the present invention.

FIG. 2 is a plan view of a portion of the shielding member drive mechanism in the vacuum vapor deposition apparatus shown in FIG. 1.

FIG. 3 is a cross-sectional view taken along line III-III of FIG. 2.

### DETAILED DESCRIPTION

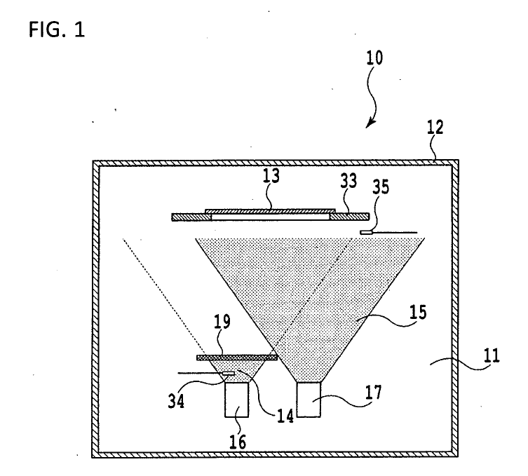

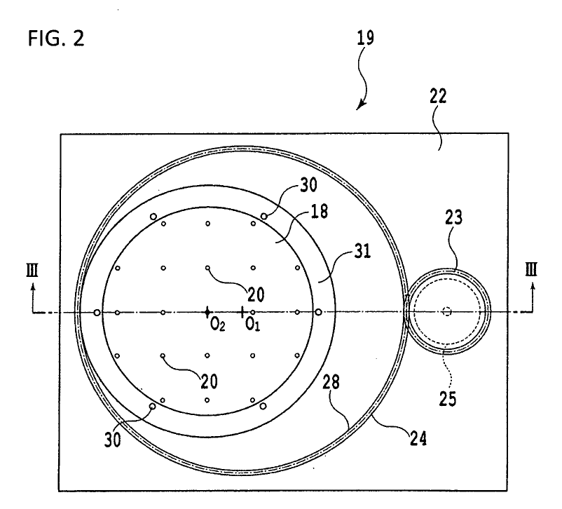

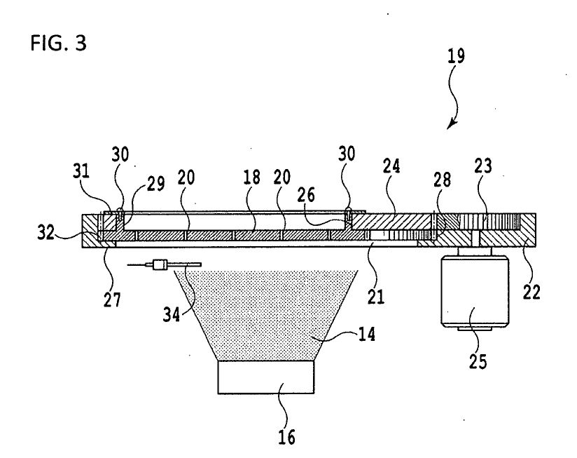

The present invention will be described below in further detail with reference to FIG. 1 to FIG. 3, based on an embodiment the film is deposited on a substrate of an organic EL (electroluminescence) material.

Referring to FIG. 1 a vacuum vapor deposition apparatus 10 of the illustrated embodiment has a container 12 having a vacuum chamber 11 inside thereof, and a vacuum pump (not shown in the figure) connected to the container 12 so as to communicate with the inside of the vacuum chamber 11, and serves to maintain a predetermined degree of vacuum inside the vacuum chamber 11. A substrate 13 serving as a work can be introduced into the container 12 and removed therefrom. A door (not shown in the figure) that can be opened and closed for moving the substrate 13, namely the work, in or out of the container, and for supplying, to the first and second vapor deposition sources, the below described first and second vapor deposition materials, namely a guest material 14 and a host material 15, is provided in the container. The inside of the vacuum chamber 11 can be accessed via the door.

First and second vapor deposition sources 16, 17 having a cup-like shape are disposed at a predetermined distance from each other inside the container 12, namely in the lower portion of the vacuum chamber 11. The guest material 14 and the host material 15 that will be vapor deposited on the surface of substrate 13 are accommodated in these first and second vapor deposition sources 16, 17, respectively. A heating apparatus (not shown in the figure) each can be incorporated into these first and second vapor deposition sources 16, 17, and the guest material 14 and the host material 15 can be independently heated with the heating apparatuses to a temperature at which the materials can be vaporized.

Examples of the guest material 14 and the host material 15 in the present embodiment include organic materials, such as organic EL materials or materials for organic solar cells, and metals, such as lithium, cesium, lithium fluoride, and alloys containing at least one thereof. Examples of the aforementioned organic EL materials include tris(8-hydroxyquinolinate) aluminum complex (Alq3), N,N′-bis(3-methylphenyl)-(1,1′-biphenyl)-4,4′-diamine (TPD), 4,4′-bis[N-(1-naphtyl)-N-phenyl-amino]biphenyl (α-NPD), quinacridone, rubrene, oxadiazole, bathocuproin, and bathophenanthroline. Examples of materials for organic solar cells include perylene derivatives, phthalocyanine derivatives, and quinacridone derivatives. The work, namely the substrate 13, usable in the present embodiment is not particularly limited and can include materials such as glass, resins, and metals.

A shielding member 18 for reducing the deposition amount of the guest material 14 on the surface of the substrate 13 with respect to the deposition amount of the host material 15 is disposed together with the drive mechanism 19 thereof directly above the first vapor deposition source 16. The shielding member 18 in the present embodiment can have a disk-like shape, and a plurality of openings 20 for passing the guest material 14 therethrough can be arranged in a lattice-like configuration with a predetermined spacing therebetween in the shielding member. The thickness of the shielding member 18, the diameter of openings 20, and the spacing between the openings can be changed according to the ratio of the vapor deposition amount of the guest material 14 to the vapor deposition amount of the host material 15 that will be vapor deposited on the surface of substrate 13. Using a random arrangement of openings 20 is also effective. Further, the shape of openings 20 is not limited to the round shape and the openings can have any shape, provided that they form a pass-through region configured to pass the guest material 14 therethrough. Moreover, the thickness of the shielding member is not particularly limited, as long as the vapor deposition material can passes therethrough.

The sum total of the surface area of openings 20 to the surface area of the shielding member 18, i.e., the opening ratio, can be set within a range of from 1% to 50%. The thickness of the film that adheres to the substrate can easily become uneven when the sum total of the surface area of the openings with respect to the surface area of the shielding member is less than 1%. Further, where the sum total of the surface area of the openings related to the surface area of the shielding member is more than 50%, the shielding effect of the vapor deposition materials becomes degraded.

The shielding member drive mechanism 19 in the present embodiment can have a base plate 22 having a round through-hole 21 formed therein, a drive gear 23 rotatably attached to the base plate 22 adjacently to the round through-hole, and a driven gear 24 accommodated so that it can be rotated with respect to the base plate 22 in a state of engagement with the drive gear 23. The drive gear 23 is connected to a drive motor 25, and the drive gear 23 can be driven at a desired rotation speed. An eccentrically positioned hole 26 into which the shielding member 18 is rotatably mated can be positioned inside the driven gear 24. The center O₂ (e.g., second axis) of the eccentric hole 26 is offset with respect to the rotation center O₁ (e.g. first axis) of the driven gear 24. In this case, the offset amount, namely the eccentricity of the center O₂ of the eccentric hole 26 is preferably set such that the relationship thereof with the arrangement spacing of openings 20 is represented by a random or irrational number.

A flange portion 27 protruding radially inwardly on the inner side is formed at the lower end portion of the hole 21 of the base plate 22, and an inner gear portion 28 having teeth of the same shape as those of the driven gear 24 is formed on the inner peripheral surface of the hole 21 between the flange portion 27 and the driven gear 24. A tubular or annular portion 29, which can be rotatably fitted into the eccentric hole 26 of the driven gear 24, is formed in the shielding member 18, an annular locking plate 31 is mounted via a plurality of screws 30 on the distal end surface of the tubular portion 29. The shielding member 18 is thereby prevented from being pulled off (in the axial direction) from the eccentric hole 26 of the driven gear 24.

Further, an outer gear portion 32, which is engaged with part of the inner gear portion 28 formed at the base plate 22 is formed at the outer peripheral surface of the shielding member 18. Because of this outer gear portion, the shielding member 18 can perform, in accordance with the rotation of the driven gear 24, a complex movement of revolving with respect to the inner gear portion 28, while sliding along the flange portion 27. In other words, when the drive gear 23 is rotated, the shielding member 18 rotates about the central axis O₂, while also rotating or orbiting about the central axis O₁ of the driven gear 24, which is parallel to the central axis O₂ of the shielding member 18, along the surface of the flange portion 27. In this case, the effective diameter of the outer gear portion 32 of the shielding member 18 can be set with respect to the effective diameter of the driven gear 24 so as to avoid too large a difference between the rotation speed of the shielding member 18 and the rotation speed of the driven gear 24 (revolution/orbiting speed of the shielding member 18 about the central axis O₁).

The settings can be such that the rotation/orbiting speeds of the shielding member 18 about the two axes O₁, O₂ is confined to a range of from 1 rpm to 100 rpm. Where the rotation/orbiting speeds of the shielding member about the first and second axes is less than 1 rpm, the thickness of the film adhering to the substrates easily becomes uneven. Further, where the rotation/orbiting speeds of the shielding member about the first and second axes exceeds 100 rpm, turbulence occurs in the vapor flow of the vapor deposition substance so that the vapor deposition substance does not fully reach the substrate.

In the present embodiment, the second axis O₁ is set parallel to the axis O₂ of the rotation center of the shielding member 18 having a disk-like shape, and the shielding member 18 is caused to revolve or orbit about the second axis O₁. But the second axis can be set in the direction coinciding with that of the first axis O₂ so that the shielding member 18 reciprocates along the second axis. In this case, the shielding member 18 performs a complex movement including a rotation movement about the first axis and a linear reciprocating movement along the direction parallel to the second axis. The rotation movement and revolution movement also can be independently controlled with two drive motors.

A work holding device 33 is configured to fixedly hold the substrate 13, onto which the guest material 14 and host material 15 supplied from the first and second vapor deposition sources 16, 17 are to be deposited, and is disposed in the upper portion or area of the vacuum chamber 11. The work holding device 33 can have any configuration, provided that it produces no adverse effect on the substrate 13 during vapor deposition operation and can hold the substrate 13 with good stability.

In the present embodiment, because it is not necessary to move the substrate 13 during vapor deposition operation as in the Reference 1, the work holding device 33 can have a simple structure, minimizing any adverse effect produced by impurities generated from the drive mechanism needed for driving the substrate 13. In this case, the guest material 14 supplied from the first vapor deposition source 16 reaches the surface of the substrate 13 via the shielding member 18, while the host material 15 supplied from the second vapor deposition source 17 directly reaches the surface of the substrate 13. Therefore, the host material 15 is deposited on the surface of substrate 13 in an amount larger than that of the guest material 14. It is desirable for the positions of the first and second vapor deposition sources 16, 17, shielding member 18, and work holding device 33 to be adequately set so that the guest material 14 and host material 15 can be uniformly distributed over the surface of the substrate 13.

A film thickness sensor 34 for the guest material, serving to evaluate the ratio of guest material 14 supplied from the first vapor deposition source 16 (the film thickness of the guest material 14 deposited on the substrate 13 via the openings 20 of the shielding member 18), is disposed in the vicinity of the shielding member drive mechanism 19 between the first vapor deposition source 16 and the shielding member drive mechanism 19. Further, a film thickness sensor 35 for the host material serving to evaluate the mass of host material 15 supplied from the second vapor deposition source 17 (the film thickness of host material 15 deposited on the substrate 13) is disposed in the vicinity of the work holding device 33 between the second vapor deposition source 17 and the work holding device 33. Detection signals from these film thickness sensors 34, 35, which can use quartz oscillators or the like, are output to a computation and processing device, such as a CPU or controller (not shown in the figure). The operation of heating apparatuses of the first and second vapor deposition sources 16, 17 or the rotation speed of the drive gear 23 can be feedback controlled so that vapor deposition can be controlled at the desired rate.

Where the vapor deposition rate of the first vapor deposition material on the work surface is less than 0.0001 Å per second, the dope amount is insufficient, the light emission efficiency of the first vapor deposition material is low, and the desired light emission cannot be obtained. Conversely, where the vapor deposition rate of the first vapor deposition material on the work surface is more than 0.1 Å per second, light quenching occurs, thereby decreasing the light emission efficiency. Therefore, it is preferred that the vapor deposition rate of the first vapor deposition material on the work surface be within a range of from 0.0001 Å per second to 0.1 Å per second. The vapor deposition rate of from 0.0005 Å per second to 0.1 Å per second is even more preferable.

To confirm the effect of the present invention, an organic EL material was deposited on the surface of the substrate 13 using the above-described vacuum vapor deposition apparatus 10, with the conditions described below in Examples 1, 2, and the dope amount D (%) of the guest material 14 relative to the host material 15 and the spread Δ (%) of film thickness distribution of the guest material 14 were calculated. For comparison, in Comparison Example 1, the same organic EL material was deposited without revolving or orbiting the shielding member 18 about the second axis O₁, and the dope amount D (%) of the guest material 14 relative to the host material 15 and the spread Δ (%) of film thickness distribution of the guest material 14 were calculated in the same manner. In Comparison Example 2, the same organic EL material was deposited without using the shielding member 18, and the dope amount D (%) and spread Δ (%) were calculated.

The dope amount D of the guest material 14 with respect to the host material 15 is represented by D^{g}=(t_{g}/tₕ)×100, where t_{g} represents a film thickness of the guest material 14 evaluated based on data from the film thickness sensor 34 and tₕ represents a film thickness of the host material 15 evaluated based on data from the film thickness sensor 35. Further, the spread Δ of film thickness distribution of the guest material 14 in the embodiment was determined by the equation Δ={(Dₘₐₓ−Dₘᵢₙ)/Dₘₐₓ}^{max}×(1/2) by sampling portions in any 16 locations on the surface of the substrate 13 and extracting the location with the maximum dope amount Dₘₐₓ and the location with the minimum dope amount Dₘᵢₙ from the 16 locations on the surface of the substrate 13 using liquid chromatography.

In Example 1, a stainless steel sheet with an opening ratio (ratio of the sum total of surface area of openings 20 to the surface area of shielding member 18) of 10% was used as the shielding member 18. Further, rubrene (5,6,11,12-tetraphenyl naphthacene) was used as the guest material 14, and tris(8-hydroxyquinolate)aluminum complex (Alq3) was used as the host material 15. A square glass sheet with a 50 mm side and a thickness of 0.7 mm was used as the substrate 13.

Each heating apparatus used was a resistance heating system for the first and second vapor deposition sources 16, 17. The guest material 14 and host material 15 were heated to a temperature of 300° C. The vapor deposition rate of the guest material 14 was set, based on the data from the film thickness sensor 34, to 0.1 Å/sec and the vapor deposition rate of the host material 15 was set, based on the data from the film thickness sensor 35, to 0.1 Å/sec, while maintaining the degree of vacuum within the vacuum chamber 11 at 10⁻⁵ Pa. The rotation speed of the shielding member 18 was set to 10 rpm, while the orbiting revolution speed thereof was set to 7 rpm. A vapor deposited layer in which the host material 15 was doped with 0.1% guest material 14 was obtained. In Example 1, the direct and reverse rotation operations of revolution movement were repeated by reversing the operation of the drive motor 25 each time the outer gear portion 32 of the shielding member 18 made one turn (i.e., after each turn of the shielding member about its center axis O₂).

In Example 2, a stainless steel sheet with an opening ratio of 5% was used as the shielding member 18. Further, rubrene (5,6,11,12-tetraphenyl naphthacene) was used as the guest material 14, and tris(8-hydroxyquinolate)aluminum complex (Alq3) was used as the host material 15. The same square glass sheet used in Example 1 was used as the substrate 13.

The same heating apparatuses used in Example 1 were used to heat the first and second vapor deposition sources 16, 17. Again, the guest material 14 and host material 15 were heated to a temperature of 300° C. Here, the rotation speed of the shielding member 18 was set to 20 rpm and the revolution or orbiting speed thereof was set to 10 rpm. The vapor deposition rate of the guest material 14 was set, based on the data from the film thickness sensor 34, to 0.1 Å/sec and the vapor deposition rate of the host material 15 was set, based on the data from the film thickness sensor 35, to 0.1 Å/sec, while maintaining the degree of vacuum within the vacuum chamber 11 at 10⁻⁵ Pa. As a result, a vapor deposited layer in which the host material 15 was doped with 0.05% guest material 14 was obtained. The ratio of the rotation speed and revolution speed was set by changing the ratio of the pitch circle diameter of the shielding member 18 and driven gear 24, and the revolution operation was performed in the same manner as in Example 1.

In Comparative Example 1, a stainless steel sheet with the opening ratio of 10% was used as the shielding member 18. Further, rubrene (5,6,11,12-tetraphenyl naphthacene) was used as the guest material 14, and tris(8-hydroxyquinolate)aluminum complex (Alq3) was used as the host material 15. The same square glass sheet used in Example 1 was used as the substrate 13.

The same heating apparatuses used in Example 1 were used to heat the guest material 14 and host material 15 to a temperature of 300° C. The vapor deposition rate of the guest material 14 was set, based on the data from the film thickness sensor 34, to 0.1 Å/sec and the vapor deposition rate of the host material 15 was set, based on the data from the film thickness sensor 35, to 1 Å/sec, while maintaining the degree of vacuum within the vacuum chamber 11 at 10⁻⁵ Pa. The shielding member 18 was rotated about its center axis O₂ by operating the drive motor 25 with the outer gear portion 32 of the shielding member 18 engaging the drive gear 23. The rotation speed of the shielding member 18 was set to 10 rpm, and a vapor deposited layer in which the host material 15 was doped with 0.1% guest material 14 was obtained.

In Comparative Example 2, a vapor deposition film was formed on the same square glass plate under the same conditions as in Example 1, except that no shielding member 18 was used, and the vapor deposition rate of the guest material 14 was set, based on the data from the film thickness sensor 34, to 0.01 Å/sec.

The test results obtained from the above examples are shown in the Table.

THE TABLE

| | Dope amount of guest material (%) | | | | | | | Film thickness |
|---|---|---|---|---|---|---|---|---|
| | 1st | 2nd | 3rd | 4th | 5th | 6th | Standard | unevenness of |
| | time | time | time | time | time | time | deviation | guest material |
| Example 1 | 0.113 | 0.101 | 0.118 | 0.115 | 0.103 | 0.091 | 0.01 | ±3% |
| Example 2 | 0.049 | 0.051 | 0.052 | 0.049 | 0.048 | 0.05 | 0.013 | ±3% |
| Comparative | 0.101 | 0.12 | 0.113 | 0.093 | 0.099 | 0.116 | 0.011 | ±5% |
| Example 1 | | | | | | | | |
| Comparative | 0.078 | 0.114 | 0.146 | 0.12 | 0.088 | 0.135 | 0.026 | ±5% |
| Example 2 | | | | | | | | |

As shown in the Table, it was confirmed that by forming a film according to the present technique, it is possible to form a vapor deposited layer with a thickness that is more stable and a spread in a dope amount of the guest material 14 that is less than those in the case where the conventional technology is used. It was also confirmed that by imparting complex motion to the shielding member 18, it is also possible to decrease the spread in the thickness of the guest material 14.

Because the shielding member is introduced between the first vapor deposition source and the work held by the work holder, the amount of the first vapor deposition material that adhered to the work surface can be greatly reduced with respect to that of the second vapor deposition material. Further, because the shielding member is rotated about the first and second axes to generate a complex motion, the adhesion distribution of the first vapor deposition material to the work surface is made more even. Therefore, the first vapor deposition material can be uniformly distributed over the work surface even when the vapor deposition amount of the first vapor deposition material is set much lower than the vapor deposition amount of the second vapor deposition material. Moreover, because, the drive mechanism and drive source can be simplified by comparison with those of the vacuum vapor deposition apparatus disclosed in the Reference, impurities generated during vapor deposition can be controlled and a high-quality vapor deposited film can be formed on the work surface.

Where the sum total of the surface area of the openings related to the surface area of the shielding member is within a range of from 1% to 50%, the ratio of the first vapor deposition material that adheres to the work surface can be adjusted with respect to the second vapor deposition material, and the vapor deposition amount of the first vapor deposition material on the work surface can be significantly less than that of the second vapor deposition material.

The shielding member drive mechanism can have a simpler structure where the shielding member is a disk, the first axis passes perpendicular to the surface of the shielding member through the center thereof, the second axis is parallel to the first axis, and the movement of the shielding member with respect to the second axis is the rotation of the shielding member about the second axis.

Where the movement of the shielding member is performed within a plane including the surface of the shielding member, hardly any turbulence occurs in the vapor flow of the first vapor deposition material within the vacuum chamber and the first vapor deposition material can be more uniformly distributed over the work surface. In particular, the mechanism for driving the shielding member can have a simple structure when the movement of the shielding member involves rotation about a first axis and revolution about a second axis parallel to the first axis. Further, when the rotation speed of the shielding member about the first axis, or the rotation speed of the shielding member about the second axis is set within a range of from 1 rpm to 100 rpm, hardly any turbulence occurs in the vapor flow of the first vapor deposition material within the vacuum chamber and the first vapor deposition material can be more uniformly distributed over the work surface.

Where the vapor deposition rate of the first vapor deposition material on the work surface is set within a range of from 0.001 Å per second to 0.005 Å per second, the vapor deposition amount of the first vapor deposition material on the work surface can be significantly less than that of the second vapor deposition material.

With the vapor deposited article in accordance with the present invention, a high-quality vapor deposited article with uniform distribution of the first vapor deposition material can be obtained even when the ratio of the vapor deposition amount of the first vapor deposition material to the vapor deposition amount of the second vapor deposition material is 1/2000 or more.

While the present invention has been particularly shown and described with reference to exemplary embodiments and examples, it will be understood by those skilled in the art that the foregoing and other changes in form and details can be made therein without departing from the spirit and scope of the present invention. All modifications and equivalents attainable by one versed in the art from the present disclosure within the scope and spirit of the present invention are to be included as further embodiments of the present invention. The scope of the present invention accordingly is to be defined as set forth in the appended claims.

This application is based on and claims priority to Japanese Patent Applications 2007-302265 filed on 21 Nov. 2007. The disclosure of the priority application in its entirety, including the drawings, claims, and the specification thereof, is incorporated herein by reference.

What is claimed is:

1. A vacuum vapor deposition apparatus comprising:
a vacuum chamber;
first and second vapor deposition sources disposable within the vacuum chamber;
a work holding device configured to fixedly hold a work inside the vacuum chamber, the work having a surface onto which first and second vapor deposition materials supplied from the first and second vapor deposition sources are depositable;
a shielding member positioned between the first vapor deposition source and the work held by the work holding device and configured to allow a vapor deposition amount of the first vapor deposition material deposited on the work surface to be less than a vapor deposition amount of the second vapor deposition material deposited on the work surface;
a shielding member drive mechanism that rotates the shielding member about a first axis while moving the shielding member with respect to a second axis that is spaced from the first axis; and
at least one drive source that drives the shielding member via the shielding member drive mechanism.

2. The vacuum vapor deposition apparatus according to claim 1, wherein the shielding member has a plurality of openings for passing the first vapor deposition material therethrough.

3. The vacuum vapor deposition apparatus according to claim 2, wherein a sum total of a surface area of the openings with respect to a surface area of the shielding member is within a range of from 1% to 50%.

4. The vacuum vapor deposition apparatus according to claim 1, wherein the shielding member is a disk, the first axis extends perpendicular to a major surface of the shielding member and through the center thereof, the second axis is parallel to the first axis, and the movement of the shielding member with respect to the second axis is a rotation of the shielding member about the second axis while the shield member is rotating about the first axis.

5. The vacuum vapor deposition apparatus according to claim 2, wherein the shielding member is a disk, the first axis extends perpendicular to a major surface of the shielding member and through the center thereof, the second axis is parallel to the first axis, and the movement of the shielding member with respect to the second axis is a rotation of the shielding member about the second axis while the shield member is rotating about the first axis.

6. The vacuum vapor deposition apparatus according to claim 3, wherein the shielding member is a disk, the first axis extends perpendicular to a major surface of the shielding member and through the center thereof, the second axis is parallel to the first axis, and the movement of the shielding member with respect to the second axis is a rotation of the shielding member about the second axis while the shield member is rotating about the first axis.

7. The vacuum vapor deposition apparatus according to claim 1, wherein a ratio of the vapor deposition amount of the first vapor deposition material deposited on the work surface to the vapor deposition amount of the second vapor deposition material deposited on the work surface is 1/1000 or less.

8. A vacuum vapor deposition method of depositing first and second vapor deposition materials, supplied from first and second vapor deposition sources disposed within a vacuum chamber, on a surface of a work fixedly held inside the vacuum chamber, the method comprising the steps of:
disposing a shielding member, which shields part of the first vapor deposition material supplied from the first vapor deposition source, between the first vapor deposition source and the work; and
moving the shielding member about at least two spaced axes while depositing the first and second deposition materials on the work surface.

9. The vacuum vapor deposition method according to claim 8, wherein the moving step moves the shielding member about a plane that includes a major surface of the shielding member.

10. The vacuum vapor deposition method according to claim 9, wherein the moving step includes rotating the shielding member about a first axis while revolving the shielding member about a second axis that is spaced from and parallel with the first axis.

11. The vacuum vapor deposition method according to claim 10, wherein a rotation speed of the shielding member about the first axis is within a range of from 1 rpm to 100 rpm.

12. The vacuum vapor deposition method according to claim 10, wherein a rotation speed of the shielding member about the second axis is within a range of from 1 rpm to 100 rpm.

13. The vacuum vapor deposition method according to claim 11, wherein a rotation speed of the shielding member about the second axis is within a range of from 1 rpm to 100 rpm.

14. The vacuum vapor deposition method according to claims 8, wherein the vapor deposition rate of the first vapor deposition material on the work surface is within a range of from 0.0001 Å per second to 0.1 Å per second.

15. The vacuum vapor deposition method according to claims 9, wherein the vapor deposition rate of the first vapor deposition material on the work surface is within a range of from 0.0001 Å per second to 0.1 Å per second.

16. The vacuum vapor deposition method according to claims 10, wherein the vapor deposition rate of the first vapor deposition material on the work surface is within a range of from 0.0001 Å per second to 0.1 Å per second.

17. The vacuum vapor deposition method according to claims 11, wherein the vapor deposition rate of the first vapor deposition material on the work surface is within a range of from 0.0001 Å per second to 0.1 Å per second.

18. The vacuum vapor deposition method according to claims 12, wherein the vapor deposition rate of the first vapor deposition material on the work surface is within a range of from 0.0001 Å per second to 0.1 Å per second.

19. The vacuum vapor deposition method according to claims 13, wherein the vapor deposition rate of the first vapor deposition material on the work surface is within a range of from 0.0001 Å per second to 0.1 Å per second.

20. The vacuum vapor deposition method according to claim 8, wherein a ratio of the vapor deposition amount of the first vapor deposition material deposited on the work surface to the vapor deposition amount of the second vapor deposition material deposited on the work surface is 1/1000 or less.
